(19) United States
(12) Patent Application Publication
(10) Pub. No.: US 2013/0022760 A1
(43) Pub. Date: Jan. 24, 2013

(54) PLASMA NITRIDING METHOD

(71) Applicants: Toshinori Debari, Yamanashi (JP); Masaki Sano, Yamanashi (JP)

(72) Inventors: Toshinori Debari, Yamanashi (JP); Masaki Sano, Yamanashi (JP)

(73) Assignee: TOKYO ELECTRON LIMITED, TOKYO (JP)

(21) Appl. No.: 13/637,502

(22) PCT Filed: Mar. 30, 2011
(86) PCT No.: PCT/JP11/57956

§ 371 Date: Sep. 26, 2012

(30) Foreign Application Priority Data
Mar. 31, 2010 (JP) 2010-081985

(51) Int. Cl. C23C 16/22; H05H 1/46

(52) U.S. Cl. 427/575; 427/569

(57) ABSTRACT

A plasma nitriding method includes performing a high nitrogen-dose plasma nitriding process on an object having an oxide film by introducing a processing gas containing a nitrogen gas into a processing chamber of a plasma processing apparatus and generating a plasma containing a high nitrogen dose; and performing a low nitrogen-dose plasma nitriding process on the object by generating a plasma containing a low nitrogen dose. After the performing the high nitrogen-dose plasma nitriding process is completed, a plasma seasoning process is performed in the chamber by generating a nitrogen plasma containing a trace amount of oxygen by introducing a rare gas, a nitrogen gas and an oxygen gas into the chamber and setting a pressure in the chamber in a range from about 532 Pa to 833 Pa and a volume flow rate ratio of the oxygen gas in all the gases in a range from about 1.5% to 5%.

### FIELD OF THE INVENTION

The present invention relates to a plasma nitriding method.

### BACKGROUND OF THE INVENTION

A plasma processing apparatus for performing a process such as film formation or the like by using a plasma is employed in a manufacturing process of various semiconductor devices fabricated on, e.g., a silicon semiconductor or a compound semiconductor, a FPD (Flat Panel Display) represented by a liquid crystal display (LCD), and the like. In this plasma processing apparatus, a component made of a dielectric material such as quartz or the like is widely used for a component in the processing chamber. For example, there is known a microwave-excited plasma processing apparatus for generating a plasma by introducing a microwave into a processing chamber through a planar antenna having a plurality of slots. This microwave-excited plasma processing apparatus is configured to generate a high-density plasma by exciting a processing gas by an electric field generated in the processing chamber by introducing a microwave transmitted to the planar antenna into a space in the processing chamber through a microwave transmitting plate made of quartz (also referred to as a ceiling plate or a transmitting plate) (see, e.g., International Patent Application Publication No. 2008/146805).

In International Patent Application Publication No. 2008/146805, the following steps are described as pre-processing steps of a plasma nitriding process. First, a dummy wafer is loaded into a chamber and mounted on a susceptor. The atmosphere in the chamber is set to a predetermined vacuum level. Then, an oxidizing plasma is generated by introducing a microwave into the chamber to excite an oxygen-containing gas. Next, a nitriding plasma is generated by introducing a microwave into the chamber to excite a nitrogen-containing gas while vacuum-evacuating the chamber. After the nitriding plasma is generated for a predetermined period of time, the dummy wafer is unloaded from the chamber and the pre-processing steps are completed.

In the plasma nitriding step, first, a wafer having an oxide film (oxidation wafer) is loaded into the chamber and, then, a nitrogen-containing gas is introduced into the chamber while the chamber is vacuum-evacuated. Thereafter, the nitrogen-containing gas is excited by introducing a microwave into the chamber, thereby generating a plasma. Next, a plasma nitriding process is performed on the oxide film of the wafer by using the plasma thus generated.

In addition, there is suggested, as a method for purifying a chamber, a method for alternately performing a step of generating a plasma of an oxygen-containing gas and a step of generating a plasma of a nitrogen-containing gas in the chamber at least one cycle (see, e.g., International Patent Application Publication No. 2005/074016) in a plasma processing apparatus for performing a process such as film formation or the like by using a plasma.

When different processes are performed in different steps in a single processing chamber, e.g., when the first process is a high nitrogen-dose plasma nitriding and the second process is a low nitrogen-dose plasma nitriding, there occurs a so-called memory effect in which the atmosphere of the first process (containing residual nitrogen ions or the like) is maintained. Due to the memory effect, the nitrogen dose does not satisfy a desired level in an initial stage of the second process.

In order to reduce the influence of the memory effect, it is required to perform, between the first process and the second process, low nitrogen-dose plasma nitriding under the same conditions as those of the second process by using a plurality of unreusable dummy wafers, each having an oxide film such as silicon dioxide (SiO₂) or the like. In this method, since the dummy wafers cannot be reused, automatization cannot be achieved. Therefore, a user needs to set manually the dummy wafers one by one, which is a troublesome work. Further, a long period of time is required until the second process becomes stable without being affected by the memory effect, thereby deteriorating the productivity and making it difficult to carry out the mass production.

### SUMMARY OF THE INVENTION

In view of the above, the present invention provides a plasma nitriding method capable of obtaining a stable low nitrogen-dose plasma state during a short period of time when a high nitrogen-dose plasma nitriding is shifted to a low nitrogen-dose plasma nitriding.

In accordance with an aspect of the present invention, there is provided a plasma nitriding method including carrying out a high nitrogen-dose plasma nitriding process on a target object to be processed having an oxide film by introducing a processing gas containing a nitrogen gas into a processing chamber of a plasma processing apparatus and generating a plasma containing a high nitrogen dose; and carrying out a low nitrogen-dose plasma nitriding process on the target object by generating a plasma containing a low nitrogen dose, wherein, after the carrying out the high nitrogen-dose plasma nitriding process is completed, a plasma seasoning process is carried out in the processing chamber by generating a nitrogen plasma containing a trace amount of oxygen by introducing a rare gas, a nitrogen gas and an oxygen gas into the processing chamber and setting a pressure in the processing chamber in a range from about 532 Pa to 833 Pa and a volume flow rate ratio of the oxygen gas in all the gases in a range from about 1.5% to 5%.

A desired value of the nitrogen dose to the target object in the high nitrogen-dose plasma nitriding process may equal to or greater than 10×10¹⁵ atoms/cm² and equal to or less than 50×10¹⁵ atoms/cm², and a desired value of the nitrogen dose to the target object in the low nitrogen-does plasma nitriding process may equal to or greater than 1×10¹⁵ atoms/cm² and less than 10×10¹⁵ atoms/cm².

The plasma may be a microwave-excited plasma formed by the processing gas and a microwave introduced into the processing chamber through a planar antenna having a plurality of slots.

A power of the microwave in the plasma seasoning process may range from about 1000 W to 1200 W and preferably from about 1050 W to 1150 W.

With the plasma nitriding method in accordance with the aspect of the present invention, when the high nitrogen-dose plasma nitriding process is shifted to the low nitrogen-dose plasma nitriding process, the plasma seasoning process is performed by using a nitrogen plasma containing a trace amount of oxygen under the conditions in which a pressure in a processing container (chamber) ranges from about 532 Pa to 833 Pa and a volume flow rate ratio of an oxygen gas in all the gases ranges from about 1.5% to 5%. Accordingly, when the high nitrogen-dose plasma nitriding process is shifted to the low nitrogen-dose plasma nitriding process, the memory effect is reduced, so that the low nitrogen-dose plasma nitriding process can be stabilized in a short period of time. Moreover, the low nitrogen plasma nitriding can be stably carried out.

### BRIEF DESCRIPTION OF THE DRAWINGS

The objects and features of the present invention will become apparent from the following description of embodiments, given in conjunction with the accompanying drawings, in which:

FIG. 1 is a cross-sectional view schematically showing a configuration of a plasma nitriding apparatus suitable for implementation of a plasma nitriding method in accordance with an embodiment of the present invention;

FIG. 2 shows a configuration example showing a planar antenna;

FIG. 3 explains a configuration example of a control unit;

FIG. 4 explains an outline of the plasma nitriding method in accordance with the embodiment of the present invention;

FIG. 5 explains variation of a nitrogen dose caused by a memory effect when a high nitrogen-dose plasma nitriding process is shifted to a low nitrogen-dose plasma nitriding process;

FIG. 6 explains variation of a nitrogen dose when a plasma seasoning process is performed during the shift from the high nitrogen-dose plasma nitriding process to the low nitrogen-dose plasma nitriding process;

FIG. 7 explains temporal changes of the amounts of nitrogen and oxygen in a processing chamber when a nitriding process is performed in the processing chamber;

FIG. 8 shows an example of a test result on dummy wafer dependency (substrate dependency) of a stable nitrogen dose;

FIG. 9 shows an example of a result of a test in which a pressure condition is varied in a plasma seasoning process;

FIG. 10 shows an example of a result of a test in which a total flow rate of a processing gas is varied in the plasma seasoning process; and

FIG. 11 shows an example of a result of a test in which a volume flow rate ratio of O₂ gas is varied in the plasma seasoning process.

### DETAILED DESCRIPTION OF THE EMBODIMENTS

Hereinafter, a plasma nitriding method in accordance with an embodiment of the present invention will be described in detail with reference to the accompanying drawings.

(Plasma Nitriding Apparatus)

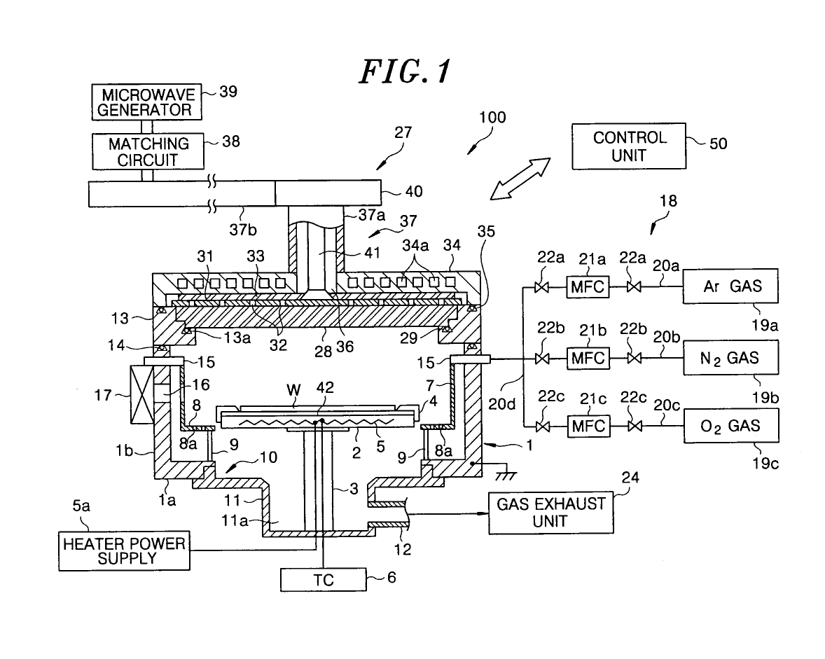

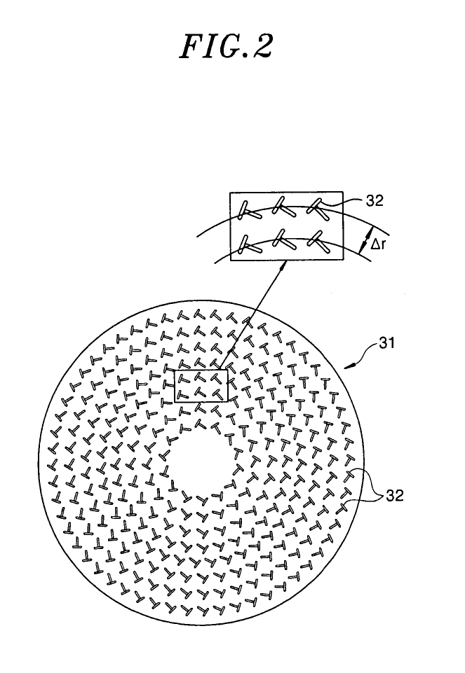

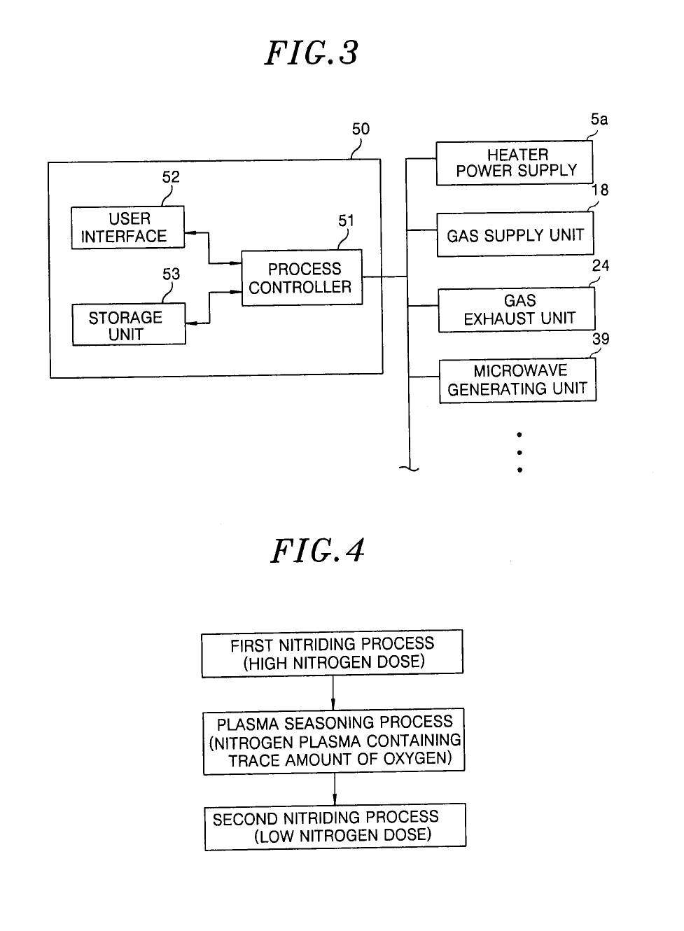

First, a configuration of a plasma nitriding apparatus that may be used in the plasma nitriding method in accordance with the embodiment of the present invention will be described with reference to FIGS. 1 to 3. FIG. 1 is a cross-sectional view schematically showing a configuration of the plasma nitriding apparatus 100. FIG. 2 is a plan view showing a planar antenna of the plasma nitriding apparatus 100 shown in FIG. 1. FIG. 3 shows a configuration of a control system of the plasma nitriding apparatus 100.

The plasma nitriding apparatus 100 is configured as an RLSA (Radial Line Slot Antenna) microwave plasma processing apparatus capable of generating a microwave-excited plasma with a high density and a low electron temperature in a processing chamber by introducing a microwave into the processing chamber through a planar antenna, particularly, a RLSA, having a plurality of slot-shaped holes. In the plasma nitriding apparatus 100, a process can be performed by a plasma with a plasma density in a range from 1×10¹⁰ to 5×10¹²/cm³ and a low electron temperature in a range from 0.7 to 2 eV. Accordingly, the plasma nitriding apparatus 100 may be suitably used for the purpose of forming a nitride film such as a silicon nitride film (SiN film) or the like in a manufacturing process of various semiconductor devices.

The plasma nitriding apparatus 100 includes, as main elements, a processing chamber 1 for accommodating therein a semiconductor wafer W (hereinafter, simply referred to as “wafer”) serving as a target object to be processed; a mounting table 2 for mounting thereon the wafer W in the processing chamber 1; a gas supply unit 18, connected to a gas inlet 15 for introducing a gas into the processing chamber 1; a gas exhaust unit 24 for vacuum-evacuating the processing chamber 1; an microwave introducing unit 27 provided at an upper portion of the processing chamber 1 to introduce a microwave into the processing chamber 1; and a control unit 50 for controlling various components of the plasma nitriding apparatus 100. The term “target object to be processed (wafer W)” used herein includes various films formed on a surface thereof, e.g., a polysilicon layer, a silicon dioxide film and the like. The gas supply unit 18 may not be included in the plasma nitriding apparatus 100, and an external gas supply unit may be connected to the gas inlet 15.

The processing chamber 1 is formed in an approximately cylindrical shape, which is grounded. Alternatively, the processing chamber 1 may be formed in a square tubular shape. The processing chamber 1 has an opening at an upper portion thereof, and also has a bottom wall 1a and a sidewall 1b made of aluminum or the like.

A mounting table 2 for horizontally supporting a wafer W as a target object to be processed is provided in the processing chamber 1. The mounting table 2 is formed of ceramic such as AlN, Al₂O₃ or the like. Among them, particularly, a material with a high thermal conductivity, e.g., AlN, is preferably used. The mounting table 2 is supported by a cylindrical support member 3 extending upwardly from a central bottom portion of a gas exhaust chamber 11. The support member 3 is made of, e.g., ceramic such as AlN or the like.

Further, a cover member 4 is provided in the mounting table 2 to cover an outer peripheral portion of the mounting table 2 and guide the wafer W. The cover member 4 is formed in an annular shape to cover a mounting surface and/or a side surface of the mounting table 2. The presence of the cover member 4 makes it possible to suppress the plasma from being in contact with the mounting table 2 and prevent the mounting table 2 from being sputtered. Also, it is possible to prevent the diffusion of impurities into the wafer W.

The cover member 4 is made of a material, e.g., quartz, single crystalline silicon, polysilicon, amorphous silicon, silicon nitride or the like. Among them, quartz having a good compatibility with the plasma is most preferably used. In addition, the material of the cover member 4 is preferably made of a high-purity material, such as alkali metal, metal or the like, having low concentration of impurities.

Further, a resistance heater 5 is embedded in the mounting table 2. The heater 5 is powered from a heater power supply 5a to heat the mounting table 2, thereby uniformly heating the wafer W as the target object.

A thermocouple (TC) 6 is also provided in the mounting table 2. The temperature of the mounting table 2 is measured by the thermocouple 6, so that the heating temperature of the wafer W can be controlled in a range from a room temperature to 900° C.

Furthermore, there are provided in the mounting table wafer support pins (not shown) that are used for exchanging wafers W when a wafer W is loaded into the processing chamber 1. Each of the wafer support pins is provided to protrude from and retreat below the top surface of the mounting table 2.

A cylindrical liner 7 made of quartz is provided on an inner periphery of the processing chamber 1. Further, an annular baffle plate 8 made of quartz is provided on an outer peripheral side of the mounting table 2 to uniformly evacuate the processing chamber 1. The baffle plate 8 has a plurality of gas exhaust holes 8a and is supported by support columns 9.

A circular opening 10 is formed in an approximately central portion of the bottom wall 1a of the processing chamber 1. The gas exhaust chamber 11 is provided in the bottom wall 1a to protrude downward and communicate with the opening 10. A gas exhaust line 12 is connected to the gas exhaust chamber 11, and is connected to the gas exhaust unit 24. In this way, the processing chamber 1 is configured to be vacuum-evacuated.

Provided at the upper opening of the processing chamber 1 is a frame-shape plate 13 that has a function (lid function) of opening and closing the processing chamber 1. An inner periphery of the plate 13 serves as an annular support portion 13a protruding inwardly (toward the inner space of the processing chamber). A gap between the plate 13 and the processing chamber 1 is airtightly sealed by a sealing member 14.

Provided in the sidewall 1b of the processing chamber 1 are a loading/unloading port 16 through which the wafer W is loaded/unloaded between the plasma nitriding apparatus 100 and a transfer chamber (not shown) adjacent to the plasma nitriding apparatus 100, and a gate valve 17 for opening and closing the loading/unloading port 16.

The gas inlet 15 has an annual shape and is provided at the sidewall 1b of the processing chamber 1. The gas inlet 15 is connected to the gas supply unit 18 for supplying a plasma exciting gas or nitrogen gas. Further, the gas inlet 15 may be formed in a nozzle shape or a shower shape.

The gas supply unit 18 includes gas supply sources; lines (e.g., gas lines 20a to 20d); flow rate controllers (e.g., mass flow controllers 21a to 21c); and valves (e.g., opening/closing valves 22a to 22c). The gas supply sources include, e.g., a non-reactive gas supply source 19a; a nitrogen gas supply source 19b; and an oxygen gas supply source 19c. Further, the gas supply unit 18 may further include, as a gas supply source (not shown) other than the above-described gas supply sources, e.g., a purge gas supply source or the like used when changing the atmosphere in the processing chamber 1.

For example, a rare gas may be used as a non-reactive gas supplied from the non-reactive gas supply source 19a. For example, Ar gas, Kr gas, Xe gas, He gas or the like may be used as the rare gas. Among them, particularly, Ar gas is preferably used in view of economical efficiency. In FIG. 1, Ar gas is representatively illustrated.

The non-reactive gas, the nitrogen gas and the oxygen gas are respectively supplied from the inactive gas supply source 19a, the nitrogen gas supply source 19b and the oxygen gas supply source 19c of the gas supply unit 18 through the gas lines 20a to 20c. The gas lines 20a to 20c are joined at the gas line 20d, and the gases are introduced into the processing chamber 1 through the gas inlet 15 connected to the gas line 20d. The gas lines 20a to 20c are respectively connected to the gas supply sources and provided with mass flow controllers 21a to 21c and pairs of opening/closing valves 22a to 22c disposed at an upstream side and a downstream side thereof. By such a configuration of the gas supply unit 18, it is possible to switch the supplied gases or control flow rates of the supplied gases.

The gas exhaust unit 24 includes a high-speed vacuum pump, e.g., a turbo molecular pump or the like. As described above, the gas exhaust unit 24 is connected to the gas exhaust chamber 11 of the processing chamber 1 through the gas exhaust line 12. The gas in the processing chamber 1 uniformly flows in a space 11a of the gas exhaust chamber 11, and the gas is exhausted from the space 11a through the gas exhaust line 12 by operating the vacuum pump. Accordingly, an internal pressure of the processing chamber 1 can be rapidly reduced to a predetermined vacuum level of, e.g., 0.133 Pa.

Next, a configuration of the microwave introducing unit 27 will be described. The microwave introducing unit includes, as main elements, a transmitting plate 28; a planar antenna 31; a wave-retardation member 33; a cover member 34; a waveguide 37; a matching circuit 38 and a microwave generator 39. The microwave introducing unit 27 serves as a plasma generator for generating a plasma by introducing an electromagnetic wave (microwave) into the processing chamber 1.

The transmitting plate 28, which serves to transmit a microwave, is disposed on the support portion 13a protruding inward in the plate 13. The transmitting plate 28 is made of a dielectric material, e.g., quartz or the like. A sealing member 29 such as an O-ring or the like is provided to airtightly seal a gap between the transmitting plate 28 and the support portion 13a, thereby maintaining airtightness of the processing chamber 1

The planar antenna 31 is disposed on the transmitting plate 28 (outside the processing chamber 1) to correspond to the mounting table 2. The planar antenna 31 has a disc shape. Alternatively, the planar antenna 31 may have, e.g., a rectangular plate shape without being limited to a disc shape. The planar antenna 31 is engaged with an upper end of the lid member 13.

The planar antenna 31 is formed of a conductive member, e.g., a copper plate, an aluminum plate, a nickel plate, or a plate of an alloy thereof, which is plated with gold or silver. The planar antenna 31 has a plurality of slot-shaped microwave radiation holes 32 through which the microwave is radiated. The microwave radiation holes 32 are formed in a predetermined pattern to extend through the planar antenna 31.

Each of the microwave radiation holes 32 has, e.g., an elongated rectangular shape (slot shape), as shown in FIG. 2. Further, generally, the adjacent microwave radiation holes 32 are arranged in an “L” shape. The microwave radiation holes 32 which are combined in groups in a specific shape (e.g., L shape) are wholly arranged in a concentric circular pattern.

A length and an arrangement interval of the microwave radiation holes 32 are determined based on the wavelength (λg) of the microwave in the waveguide 37. For example, the microwave radiation holes 32 are arranged at the arrangement interval ranging from λg/4 to λg. In FIG. 2, the arrangement interval between the adjacent microwave radiation holes 32 formed in the concentric circular pattern is represented as Δr. The microwave radiation holes 32 may have another shape such as a circular shape or a circular arc shape. Moreover, the microwave radiation holes 32 may be arranged in another pattern, e.g., a spiral or a radial pattern, without being limited to the concentric circular pattern.

The wave-retardation member 33 having a larger dielectric constant than that of the vacuum is disposed on an upper surface of the planar antenna 31 (a flat waveguide formed between the planar antenna 31 and the cover member 34). Since the microwave has a longer wavelength in the vacuum, the wave-retardation member 33 functions to shorten the wavelength of the microwave to effectively generate the plasma. For example, quartz, polytetrafluoroethylene resin, polyimide resin or the like may be used as the material of the wave-retardation member 33.

The planar antenna 31 may be in contact with or separated from the transmitting plate 28, but it is preferable that the planar antenna 31 is in contact with the microwave transmitting plate 28. Moreover, the wave-retardation member 33 may be in contact with or separated from the planar antenna 31, but it is preferable that the wave-retardation member 33 is in contact with the planar antenna 31.

The cover member 34 is provided at the top of the processing chamber 1 to cover the planar antenna 31 and the wave-retardation member 33. The cover member 34 is made of a metal material such as aluminum, stainless steel or the like. A flat waveguide is constituted by the cover member and the planar antenna 31, so that the microwave is propagated uniformly into the processing chamber 1. A sealing member 35 is provided to seal a gap between an upper end of the plate 13 and the cover member 34. Further, the cover member 34 has a cooling water passage 34a formed therein. The cover member 34, the wave-retardation member 33, the planar antenna 31 and the transmitting plate 28 may be cooled by flowing a cooling water through the cooling water passage 34a. Further, the cover member 34 is grounded. An opening 36 is formed in a central portion of an upper wall (ceiling) of the cover member 34. The opening 36 is connected to one end of the waveguide 37. The microwave generator 39 for generating a microwave is connected to the other end of the waveguide 37 via the matching circuit 38. The waveguide 37 includes a coaxial waveguide 37a having a circular cross sectional shape and extending upward from the opening 36 of the cover member 34; and a rectangular waveguide 37b connected to an upper end of the coaxial waveguide 37a via a mode transducer 40 and extended in a horizontal direction. The mode transducer 40 functions to convert a microwave propagating in a TE mode in the rectangular waveguide 37b into a TEM mode microwave.

An internal conductor 41 extends through the center of the coaxial waveguide 37a. A lower end of the internal conductor 41 is connected and fixed to a central portion of the planar antenna 31. With this structure, the microwave is efficiently, uniformly and radially propagated to the flat waveguide constituted by the cover member 34 and the planar antenna 31 through the internal conductor 41 of the coaxial waveguide 37a.

By the microwave introducing unit 27 having the above configuration, the microwave generated in the microwave generator 39 is propagated to the planar antenna 31 through the waveguide 37, and then introduced into the processing chamber 1 through the microwave radiation holes (slots) 32 and the transmitting plate 28. The microwave preferably has a frequency of, e.g., 2.45 GHz, but the frequency of the microwave may be 8.35 GHz, 1.98 GHz or the like.

Each component of the plasma nitriding apparatus 100 is connected to and controlled by the control unit 50

The control unit 50 is typically a computer. For example, as shown in FIG. 3, the control unit 50 includes a process controller 51 having a CPU; and a user interface 52 and a storage unit 53, which are connected to the process controller 51. The process controller 51 serves as a control unit for integratedly controlling, in the plasma nitriding apparatus 100, the respective components (e.g., the heater power supply 5a, the gas supply unit 18, the gas exhaust unit 24, the microwave generator 39 and the like) which are associated with the process conditions such as temperature, pressure, gas flow rate, microwave output and the like.

The user interface 52 includes a keyboard through which a process operator performs, e.g., an input operation in accordance with commands in order to manage the plasma nitriding apparatus 100; a display for visually displaying an operational status of the plasma nitriding apparatus 100; and the like. Further, the storage unit 53 stores a recipe including process condition data or control programs (software) for performing various processes in the plasma nitriding apparatus 100 under the control of the process controller 51.

Further, if necessary, a certain recipe is retrieved from the storage unit 53 in accordance with instructions inputted through the user interface 52 and executed by the process controller 51. Accordingly, a desired process is performed in the processing chamber 1 of the plasma nitriding apparatus 100 under the control of the process controller 51. The recipe including process condition data or control programs may be stored in a computer-readable storage medium, e.g., CD-ROM, hard disk, flexible disk, flash memory, DVD, blue-ray disc and the like. Alternatively, the recipe may be transmitted from a separate device through, e.g., a dedicated line.

In the plasma nitriding apparatus 100 having the above configuration, a plasma process may be performed at a low temperature ranging between about 25° C. (about a room temperature) and 600° C. without causing damage to the wafer W. Further, since the plasma nitriding apparatus 100 has an excellent plasma uniformity, in-plane uniformity of processing may be achieved even on a large-sized wafer W.

The following description relates to an example of the sequence of a plasma nitriding process performed on a single wafer W by using the RLSA-type plasma nitriding apparatus 100. The same sequence is carried out in both of a high nitrogen-dose processing and a low nitrogen-dose processing except that processing conditions in the processings are different from each other.

First, a wafer W is loaded into the processing chamber 1 through the loading/unloading port 16 by opening the gate valve 17, and then mounted on the mounting table 2. Then, a rare gas and nitrogen gas are respectively introduced into the processing chamber 1 at predetermined flow rates from the non-reactive gas supply source 19a and the nitrogen gas supply source 19b of the gas supply unit 18 through the gas inlet 15 while the processing chamber 1 is uniformly evacuated. In this manner, the internal pressure of the processing chamber 1 is adjusted to a predetermined level.

Then, the microwave of a predetermined frequency, e.g., 2.45 GHz, generated from the microwave generator 39 is transmitted to the waveguide 37 via the matching circuit 38. The microwave transmitted to the waveguide 37 sequentially passes through the rectangular waveguide 37b and the coaxial waveguide 37a, and is supplied to the planar antenna 31 through the internal conductor 41. The microwave propagates in a TE mode in the rectangular waveguide 37b, and the TE mode microwave is converted into a TEM mode microwave by the mode convertor 40. The TEM mode microwave propagates in the coaxial waveguide 37a toward the planar antenna 31. Then, the microwave is radiated to the space above the wafer W in the processing chamber 1, through the transmitting plate 28, from the slot-shaped microwave radiation holes 32 that are formed to extend through the planar antenna 31.

An electromagnetic field is generated in the processing chamber 1 by the microwave radiated from the planar antenna 31 into the processing chamber 1 through the transmitting plate 28, and a processing gas such as a rare gas, a nitrogen gas, or the like is converted into a plasma. At this time, the microwave is radiated through the microwave radiation holes 32 of the planar antenna 31, thereby generating such a microwave-excited plasma having a high density in a range from approximately 1×10¹⁰ to 5×10¹²/cm³ and a low electron temperature of approximately 1.2 eV or less in the vicinity of the wafer W.

The conditions of the plasma nitriding process performed by the plasma nitriding apparatus 100 may be stored as recipes in the storage unit 53 of the control unit 50. The process controller 51 reads out the recipes and transmits control signals to the components, e.g., the gas supply unit 18, the gas exhaust unit 24, the microwave generator 39, the heater power supply 5a and the like, of the plasma nitriding apparatus 1, thereby achieving the plasma nitriding process under the desired conditions.

(Sequence of Plasma Nitriding Method)

Next, a sequence of a plasma nitriding method of the present embodiment will be described with reference to FIG. 4. FIG. 4 shows a general sequence of the plasma nitriding method of the present embodiment. As shown in FIG. 4, the plasma nitriding method includes a first nitriding process; a plasma seasoning process to be performed after the first nitriding process; and a second nitriding process for performing a nitriding process different from that of the first nitriding process.

Specifically, in the first nitriding process, a step of nitriding a wafer W by a nitrogen-containing plasma is repeated while exchanging wafers W, the nitrogen-containing plasma being generated under a first plasma generation condition by introducing a nitrogen-containing processing gas into the processing chamber 1 of the plasma nitriding apparatus 100. In the plasma seasoning process which follows the first nitriding process, the amounts of residual oxygen and residual nitrogen in the processing chamber 1 after the first nitriding process is controlled by a nitrogen-containing plasma (nitrogen plasma) containing a trace amount of oxygen. In the second nitriding process, after the plasma seasoning process, a step of nitriding a wafer W by a nitrogen plasma is repeated while exchanging wafers W, the nitrogen plasma being generated under a second plasma generation condition by introducing a nitrogen-containing processing gas into the processing chamber 1 of the plasma nitriding apparatus 100.

The first nitriding process and the second nitriding process are the same in that the plasma nitriding is carried out. However, the types of the plasma nitriding performed in the first and the second nitriding process can be distinguished from each other in accordance with, e.g., a nitriding power (capability of nitriding a thin film on the wafer W) required in each of the processes. Specifically, in the plasma nitriding of the first nitriding process, the wafer W is nitrided by a nitrogen plasma generated under the first plasma generation condition. In the plasma nitriding of the second nitriding process, the wafer W is nitrided by a nitrogen plasma generated under the second plasma generation condition in which a nitrogen dose to the wafer W becomes lower than that in the plasma nitriding of the first nitriding process.

In the present embodiment, the terms “high nitrogen dose” and “low nitrogen dose” are relative expressions. A desired value of the nitrogen dose to the wafer W in the first nitriding process may be equal to or greater than, e.g., 10×10¹⁵ atoms/cm² and not greater than 50×10¹⁵ atoms/cm², and preferably equal to or greater than 15×10¹⁵ atoms/cm² and not grater than 30×10¹⁵ atoms/cm². The desired value of the nitrogen dose to the wafer W in the second nitriding process may be equal to or greater than, e.g., 1×10¹⁵ atoms/cm² and less than 10×10¹⁵ atoms/cm² and preferably equal to or greater than 5×10¹⁵ atoms/cm² and not greater than 9×10¹⁵ atoms/cm². In that case, the second plasma generation condition in which the nitriding power may be lower than that in the first plasma generation condition. Further, the nitrogen dose to the wafer W in the plasma nitriding process can be within the above range by controlling the conditions, e.g., a power of the microwave, the flow rate of a processing gas, a processing pressure and the like.

In the present embodiment, the following conditions are used as examples of the high nitrogen dose processing conditions and the low nitrogen dose processing conditions.

(High Nitrogen Dose Processing Conditions)

Processing pressure: 20 Pa

Ar gas flow rate: 48 mL/min(sccm)

N₂ gas flow rate: 32 mL/min(sccm)

Frequency of microwave: 2.45 GHz

Power of microwave: 2000 W (power density 2.8 W/cm²)

Processing temperature: 500° C.

Processing time: 110 sec

Wafer diameter: 300 mm

(Low nitrogen dose processing conditions)

Processing pressure: 20 Pa

Ar gas flow rate: 456 mL/min(sccm)

N₂ gas flow rate: 24 mL/min(sccm)

Frequency of microwave: 2.45 GHz

Power of microwave: 1000 W (power density 1.4 W/cm²)

Processing temperature: 500° C.

Processing time: 5 sec

Wafer diameter: 300 mm

In the plasma nitriding method of the present embodiment, the plasma seasoning process is performed during the shift from the high nitrogen-dose plasma process as the first nitriding process to the low nitrogen-dose plasma process as the second nitriding process, as shown in FIG. 4. The plasma seasoning process is performed to control the amounts of oxygen and nitrogen in the processing chamber 1 by generating a nitrogen plasma containing a trace amount of oxygen in the processing chamber 1.

(Sequence of Plasma Seasoning Process)

Hereinafter, a sequence of the plasma seasoning process in the plasma nitriding apparatus 100 will be described. First, the gate valve 17 is opened, and a dummy wafer is loaded into the processing chamber 1 through the loading/unloading port 16 and mounted on the mounting table 2. The dummy wafer may not be used. Next, while the processing chamber 1 is vacuum-exhausted, an inactive gas, nitrogen gas and oxygen gas are respectively introduced into the processing chamber 1 at predetermined flow rates through the gas inlet 15 from the inactive gas supply source 19a, the nitrogen gas supply source 19B and the oxygen gas supply source 19C of the gas supply unit 18. In this manner, the pressure in the processing chamber 1 is controlled to a predetermined level.

Next, the microwave of a predetermined frequency, e.g., 2.45 GHz, generated in the microwave generator 39 is transmitted to the waveguide 37 via the matching circuit 38. The microwave transmitted to the waveguide 37 sequentially passes through the rectangular waveguide 37b and the coaxial waveguide 37a, and is supplied to the planar antenna 31 through the internal conductor 41. The microwave propagates in the TE mode in the rectangular waveguide 37b. Thereafter, the TE mode of the microwave is converted into the TEM mode by the mode transducer 40. The TEM mode microwave propagates in the coaxial waveguide 37a toward the planar antenna 31. Then, the microwave is radiated to the space above the wafer W in the processing chamber 1, through the transmitting plate 28, from the slot-shaped microwave radiation holes 32 that are formed to extend through the planar antenna 31.

An electromagnetic field is generated in the processing chamber 1 by the microwave radiated into the processing chamber 1 from the planar antenna 31 through the transmitting plate 28, so that the inactive gas, the nitrogen gas and the oxygen gas are converted into a plasma. At this time, the microwave is radiated through the microwave radiation holes 32 of the planar antenna 31, thereby generating a plasma having a high density in a range from about 1×10¹⁰/cm³ to 5×10¹²/cm³ and a low electron temperature of about 1.2 eV or less in the vicinity of the wafer W.

(Conditions of Plasma Seasoning Process)

The following description relates to desired conditions of a plasma seasoning process performed by the plasma nitriding apparatus 100.

<Processing Gas>

As for a processing gas for the plasma seasoning process, it is preferable to use N₂ gas, O₂ gas and Ar gas as a rare gas. At this time, a flow rate ratio (volume ratio) of N₂ gas contained in the processing gas is preferably ranges from about 2% to 8%, and more preferably ranges from about 4% to 6%, in view of alleviating a N₂ atmosphere as much as possible. Further, a flow rate ratio (volume ratio) of O₂ gas contained in the processing gas is preferably ranges from about 1.5% to 5% and more preferably ranges from about 1.5% to 2.5% in view of creating a mild O₂ atmosphere. Moreover, a flow rate ratio of the N₂ gas and the O₂ gas contained in the processing gas (volume ratio; N₂ gas:O₂ gas) is preferably within the range of, e.g., about 1.5:1 to 4:1 and more preferably within the range from about 2:1 to 3:1 in view of adding an O₂ atmosphere while maintaining an N₂ atmosphere.

For example, when the wafer W having a diameter of about 300 mm is processed, the above-described flow rate ratio can be satisfied by setting a flow rate of Ar gas within the range from about 100 mL/min(sccm) to 500 mL/min(sccm), a flow rate of N₂ gas within the range from about 4 mL/min(sccm) to 20 mL/min(sccm), and a flow rate of O₂ gas within the range from about 2 mL/min(sccm) to 10 mL/min(sccm).

<Processing Pressure>

A processing pressure in the plasma seasoning process is preferably within the range from about 532 Pa to 833 Pa and more preferably within the range from about 532 Pa to 667 Pa in view of generating a radical-dominant plasma and increasing the controllability. When a processing pressure is lower than about 532 Pa, oxygen radicals become dominant and, thus, an N₂ atmosphere disappears.

<Processing Time>

A processing time in the plasma seasoning process is preferably set in a range from, e.g., about 4 sec to 6 sec, and more preferably set in a range from, e.g., about 4.5 sec to 5.5 sec. Until a specific period of time, the effect of controlling the amount of oxygen in the processing chamber 1 is increased as the processing time is increased. However, if the processing time is excessively increased, the effect is no longer increased and the entire throughput becomes decreased. Therefore, the processing time needs to be set as shortly as possible within such a range as to obtain the effect of controlling the amount of oxygen to a desired level.

<Power of Microwave>

A power density of the microwave in the plasma seasoning process is set within the range from about 1.4 W to 1.7 W per unit area of the wafer W in view of stably and uniformly generating a nitrogen plasma as mild as possible. Therefore, when a wafer W having a diameter of about 300 mm is used, the power of the microwave is preferably set within the range from about 1000 W to 1200 W and more preferably within the range from about 1050 W to 1150 W.

<Processing Temperature>

A processing temperature (heating temperature of dummy wafer) as the temperature of the mounting table 2 is preferably set within the range from about a room temperature (about 25° C.) to about 600° C., more preferably within the range from about 200° C. to 500° C., and most preferably within the range from about 400° C. to 500° C.

The conditions of the plasma seasoning process using a nitrogen plasma containing a trace amount of oxygen which is performed by the plasma nitriding apparatus 100 may be stored as recipes in the storage unit 53 of the control unit 50. Further, the process controller 51 reads out the recipes and transmits control signals to the respective components of the plasma nitriding apparatus 100, e.g., the gas supply unit 18, the gas exhaust unit 24, the microwave generator 39, the heater power supply 5a and the like. Accordingly, the plasma seasoning process is realized under desired conditions.

Next, a test result in accordance with the embodiment of the present invention will be described. FIG. 5 explains an example of changes of a nitrogen dose in the case of performing no plasma seasoning process during the shift from the high nitrogen-dose plasma process as the first nitriding process to the low nitrogen-dose plasma process as the second nitriding process. In FIG. 5, the horizontal axis indicates time, and the vertical axis indicates a nitrogen dose [×10¹⁵ atoms/cm²]. In that case, a reference value of a nitrogen dose in the high nitrogen-dose plasma process is set to be, e.g., about 20×10¹⁵ atoms/cm² or above, and a reference value of a nitrogen dose in the low nitrogen-dose plasma process is set to be, e.g., about 9×10¹⁵ atoms/cm² or less.

As shown in FIG. 5, even after the high nitrogen-dose plasma process is shifted to the low nitrogen-dose plasma process, the dummy wafers D1 to D3 do not satisfy the reference value of the nitrogen dose, which indicates that a considerable period of time is required until a desired low nitrogen dose (e.g., about 8×10¹⁵ atoms/cm² in FIG. 5) is stably obtained. In other words, FIG. 5 shows that there occurs a so-called memory effect in which the atmosphere of the high nitrogen-dose plasma process (nitrogen ions or the like) as the first process is maintained.

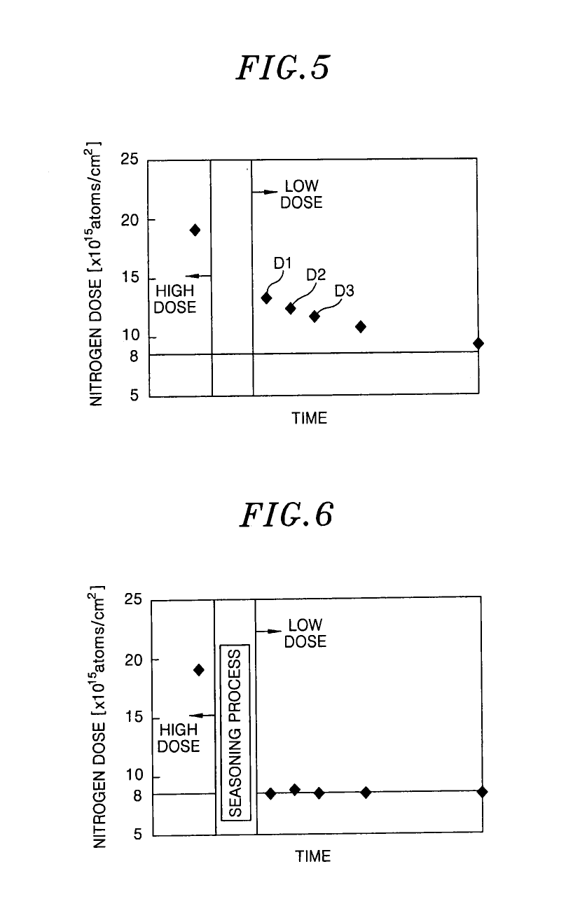

FIG. 6 explains an example of changes of a nitrogen dose when a plasma seasoning process is performed in the processing chamber 1 by using a nitrogen plasma containing a trace amount of oxygen before the high nitrogen-dose plasma process as the first nitriding process is shifted to the low nitrogen-dose plasma process as the second nitriding process, which characterizes the embodiment of the present invention.

Similarly to FIG. 5, in FIG. 6, the horizontal axis indicates time, and the vertical axis indicates a nitrogen dose [×10¹⁵ atoms/cm²]. In FIG. 6, a nitrogen dose of about 9×10¹⁵ atoms/cm² or less which corresponds to the reference value in the low nitrogen-dose plasma process can be stably obtained immediately after the low nitrogen-dose plasma process is started. As clearly can be seen from FIGS. 5 and 6, by performing the plasma seasoning process of the present embodiment, the nitrogen dose is rapidly stabilized to a desired low nitrogen dose (e.g., about 8×10¹⁵ atoms/cm² in FIG. 6) immediately after the low nitrogen-dose plasma process is started upon completion of the high nitrogen-dose plasma process. Therefore, in accordance with the plasma nitriding method of the present embodiment, the memory effect is eliminated by performing the plasma seasoning process, so that a desired process can be rapidly carried out during the low nitrogen-dose plasma nitriding process as the second nitriding process.

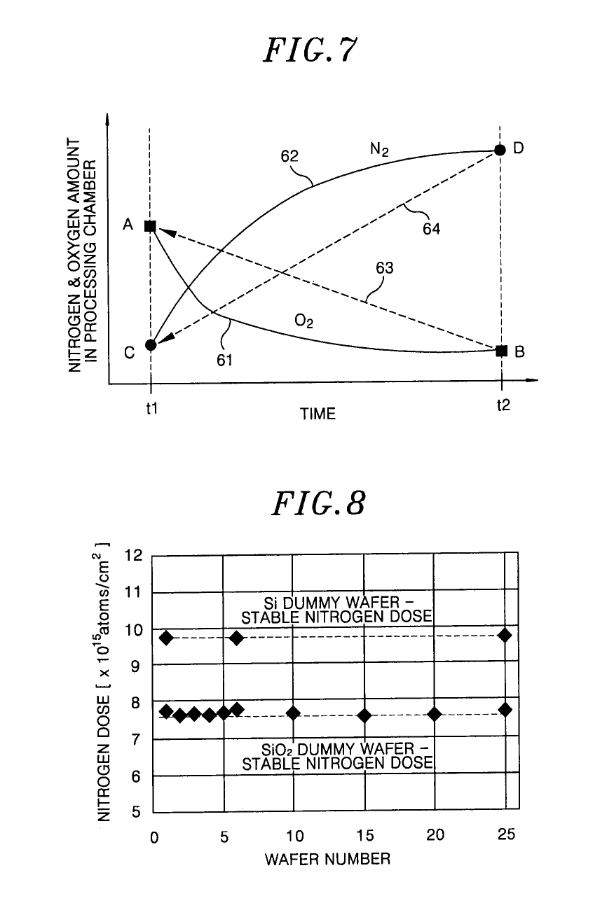

FIG. 7 explains temporal changes of the amounts of nitrogen and oxygen in the processing chamber 1 when a high nitrogen-dose plasma nitriding process is performed on a plurality of wafer W in the processing chamber 1. In the processing chamber 1, components made of, e.g., quartz are widely used. However, a surface of quartz is nitrided by the plasma nitriding process to form a SiN film or the SiN film formed on the surface of quartz is thinly oxidized during the repetition of the plasma nitriding process to form a SiON film in a process in which a large amount of oxygen is discharged from an oxygen-containing film (e.g., silicon dioxide film) on an object to be processed.

As such, in the processing chamber 1 where the plasma nitriding process is performed, the amounts of nitrogen and oxygen are varied depending on the conditions of the plasma nitriding process. In FIG. 7 in which the horizontal axis indicates time and the vertical axis indicates the amounts of nitrogen and oxygen in an atmosphere in the processing chamber 1, there are illustrated changes of the amounts of nitrogen and oxygen in the processing chamber 1. In FIG. 7, curved lines 61 and 62 present the amounts of oxygen and nitrogen in the processing chamber 1, respectively.

In FIG. 7, when a high nitrogen-dose plasma nitriding process is sequentially performed on each of a plurality of wafers W in the processing chamber 1 between time t1 and time t2, the amount of oxygen in the processing chamber 1 is temporally decreased (amount “A”→amount “B”) as clearly can be seen from the curved line 61. This is because a larger amount of oxygen is discharged from the processing chamber 1 in the high nitrogen-dose plasma nitriding process while the amount of oxygen discharged from the oxygen-containing film on the wafer W is increased.

On the other hand, as indicated by the curved line 62, the amount of nitrogen in the processing chamber 1 is gradually increased (amount “C”→amount “D”) during the plasma nitriding process that is the high nitrogen-dose plasma nitriding process. At the time t2, the nitrogen amount and the oxygen amount are stably balanced, even though the amount of nitrogen in the processing chamber 1 is large (D) and the amount of oxygen therein is small (B), which is suitable for stable performance of a high nitrogen-dose plasma process.

Here, it is assumed that a state in which the amount of nitrogen in the processing chamber 1 is small (C) and the amount of oxygen therein is large (A) is a desired condition for stably performing a low nitrogen-dose plasma process in the processing chamber 1. In that case, when the high nitrogen dose process is completed and shifted to the low nitrogen dose process at the time t2, it is difficult to stably perform the low nitrogen dose process because the amount of nitrogen in the processing chamber 1 is large (D) and the amount of oxygen in the processing chamber 1 is small (B). Accordingly, the low nitrogen dose plasma nitriding process is not stable (memory effect) at least until the amount of oxygen in the processing chamber 1 is changed from (B) to (A) and the amount of nitrogen in the processing chamber 1 is changed from (D) to (C).

Thus, in the present embodiment, the plasma seasoning using a nitrogen plasma containing a trace amount of oxygen is carried out in order to change the oxygen state for the small amount B to the large amount A and also change the nitrogen state from the large amount D to the small amount C. Accordingly, the amount of oxygen and the amount of nitrogen in the processing chamber 1 are controlled to be close to (A) and (C), respectively.

In other words, in the present embodiment, the plasma seasoning process using a nitrogen plasma containing a trace amount of oxygen is performed during the shift from the high nitrogen-dose plasma nitriding process that can be stably performed in the state where the amount of oxygen in the processing chamber 1 is small (B) and the amount of nitrogen in the processing chamber 1 is large (D) to the low nitrogen-does plasma nitriding process that can be stably performed in the state where the amount of oxygen in the processing chamber 1 is large (A) and the amount of nitrogen in the processing chamber 1 is small (C). Hence, the amount of oxygen in the processing chamber 1 is returned from the small amount B to the large amount A, as indicated by a dashed line 63 in FIG. 7. Further, the nitrogen amount in the processing chamber 1 is returned from the large amount D to the small amount C, as indicated by a dashed line 64 (Here, only the amount changes between oxygen and nitrogen are explained regardless of time).

The plasma processing method of the present embodiment aims to control the amounts of oxygen and nitrogen in the processing chamber 1 to be suitable for the low nitrogen-dose plasma nitriding process as the second process by leaving a predetermined amount of nitrogen in the processing chamber 1 at the time of the completion of the high nitrogen-dose plasma nitriding process as the first process. To that end, the plasma seasoning process is performed in the processing chamber 1 by using a nitrogen plasma containing a trace amount of oxygen. Hence, the first process may be quickly shifted to the second process, and the memory effect in the first process is suppressed, which results in improvement of a throughput.

In the conventional method disclosed in International Patent Application Publication No. 2008/146805 and the like described in “Background of the Invention” section, an atmosphere in the processing chamber 1 is forcibly reset by two kinds of plasma processes before a plasma nitriding process is carried out. Specifically, the method described in International Patent Application Publication No. 2008/146805 is different from the present embodiment in that nitrogen in the processing chamber 1 is completely removed by forcibly supplying oxygen into the processing chamber 1 by an oxygen plasma process, and then the amounts of nitrogen and oxygen in the processing chamber 1 are controlled to an atmosphere suitable for nitriding an oxide film by the nitrogen plasma process. The plasma processing method of the present embodiment is advantageous in that the same effects as those of the conventional method can be obtained by one plasma seasoning process.

Next, an example of a test result on dummy wafer dependency (substrate dependency) of a stable nitrogen dose will be described. FIG. 8 shows an example of a result of a test on substrate dependency (dummy wafer dependency) of a stable nitrogen dose in the plasma nitriding apparatus having the same configuration as that of the plasma nitriding apparatus 100. In the present embodiment, a Si dummy wafer made of silicon and a SiO₂ dummy wafer having a silicon dioxide film were used as processing target dummy wafers, and monitoring was performed at a regular interval during the test. In FIG. 8, the horizontal axis indicates a wafer number, and the vertical axis indicates a nitrogen dose [×10¹⁵ atoms/cm²].

The following description relates to conditions of a plasma nitriding process in this test.

(Plasma Nitriding Process Conditions)

Processing pressure: 20 Pa

Ar gas flow rate: 228 mL/min(sccm)

N₂ gas flow rate: 12 mL/min(sccm)

O₂ gas flow rate: 0 mL/min(sccm)

Frequency of microwave: 2.45 GHz

Power of microwave: 1100 W (power density 1.6 W/cm²)

Processing temperature: 500° C.

Processing time: 20 sec

Wafer diameter: 300 mm

As can be seen from FIG. 8, when the Si dummy wafer is monitored, wafer Nos. 1, 6 and 25 respectively have nitrogen doses of about 9.76×[10¹⁵ atoms/cm²]; 9.74×[10¹⁵ atoms/cm²]; and 9.76×[10¹⁵ atoms/cm²]. As such, when the Si dummy wafer is monitored, the nitrogen dose becomes stable at about 9.7×10¹⁵ atoms/cm².

Meanwhile, in the case of using the SiO₂ dummy wafer having a silicon dioxide film, wafer Nos. 1, 2, 3, 4, 5, 6, 10, 15, 20 and 25 respectively have nitrogen doses of about 7.70×10¹⁵ atoms/cm²; 7.63×10¹⁵ atoms/cm²; 7.67×10¹⁵ atoms/cm²; 7.65×10¹⁵ atoms/cm²; 7.68×10¹⁵ atoms/cm²; 7.77×10¹⁵ atoms/cm²; 7.65×10¹⁵ atoms/cm²; 7.59×10¹⁵ atoms/cm²; 7.59×10¹⁵ atoms/cm²; and 7.70×10¹⁵ atoms/cm². When the SiO₂ dummy wafer is monitored, the nitrogen dose ranges from about 7.6×10¹⁵ atoms/cm² to 7.8×10¹⁵ atoms/cm² and becomes stable at a lower level compared to the case of using the Si dummy wafer.

In accordance with the test using two kinds of dummy wafers shown in FIG. 8, the nitrogen dose depends on the materials of the monitored dummy wafers. In other words, an atmosphere in the processing chamber 1 is changed depending on the types of films formed on the wafer W. This is because when an oxide film is used, the amounts of oxygen and nitrogen in the processing chamber 1 are balanced in a state where the amount of oxygen is large and the amount of nitrogen is small since oxygen is discharged from the oxide film. On the other hand, when silicon is used, the amounts of oxygen and nitrogen are balanced in a state where the amount of oxygen is small and the amount of nitrogen is large because oxygen is not discharged.

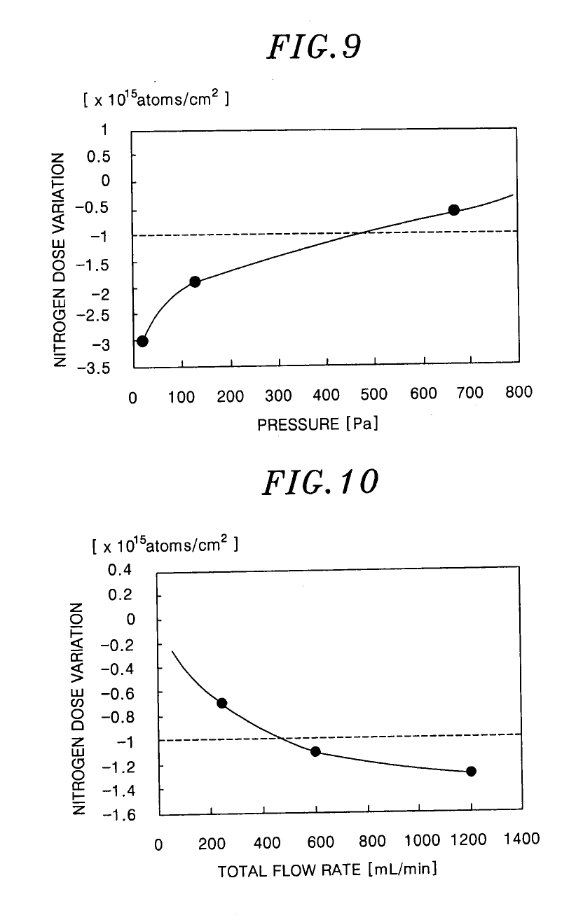

Next, an example of a test result on pressure/flow rate dependency in the plasma seasoning process will be described. FIGS. 9 to 11 show test results on the conditions of the plasma seasoning process using a nitrogen plasma containing a trace amount of oxygen. Here, the high nitrogen-dose plasma nitriding process was carried out by using a plasma nitriding apparatus having the same configuration as that of the plasma nitriding apparatus 100 and, then, the plasma seasoning process was performed by using a plasma containing a trace amount of oxygen under the following conditions.

Then, the low nitrogen-dose plasma nitriding process in which a desired value of a nitrogen dose was about 7×10¹⁵ atoms/cm² was performed. In the plasma seasoning process, an atmosphere in the processing chamber 1 was changed depending on the processing conditions. Hence, the conditions suitable for the plasma seasoning process were verified by evaluating a difference between a desired value and a nitrogen dose in the low nitrogen-dose plasma nitriding process. As for wafers W, wafers each having a surface on which a SiO₂ film was formed were used. In FIGS. 9 to 11, the vertical axis indicates a difference (×10¹⁵ atoms/cm²) in the case where a desired value of a nitrogen dose [7×10¹⁵ atoms/cm²] is assumed to be zero (0). A tolerable specification range (change of a nitrogen dose) is between about (7×10¹⁵ atoms/cm²)±1×10¹⁵ atoms/cm².

FIG. 9 shows a test result obtained by varying a pressure in the processing chamber 1 as a condition of the plasma seasoning process using a nitrogen plasma containing a trace amount of oxygen. In this test, a processing pressure was varied under the following plasma seasoning conditions A.

(Plasma Seasoning Conditions A)

Processing pressure: 20 Pa, 127 Pa or 667 Pa

Ar gas flow rate: 228 mL/min(sccm)

N₂ gas flow rate: 12 mL/min(sccm)

O₂ gas flow rate: 5 mL/min(sccm)

Volume flow rate ratio of O₂ gas (O₂/total flow rate):2%

Total flow rate of processing gas: 245 mL/min(sccm)

Frequency of microwave: 2.45 GHz

Power of microwave: 1100 W (power density 1.6 W/cm²)

Processing temperature: 500° C.

Processing time: 5 sec

Wafer diameter: 300 mm

As can be seen from FIG. 9, the processing pressure is preferably set to about 532 Pa or above. For example, when the processing pressure is set in a range from about 532 Pa to 667 Pa, a stable nitrogen dose having small variation can be obtained. However, the same result was obtained even when the pressure was higher than about 667 Pa (e.g., about 833 Pa).

FIG. 10 shows a test result obtained by varying a total flow rate of a processing gas as a condition of the plasma seasoning process using a nitrogen plasma containing a trace amount of oxygen. In this test, the variation of a nitrogen dose was examined by varying the total flow rate of the processing gas under the following plasma seasoning conditions B.

(Plasma Seasoning Conditions B)

Processing pressure: 667 Pa

N₂ gas flow rate: 12 mL/min(sccm)

Volume flow rate ratio of O₂ gas (O₂/total flow rate):2%

Total flow rate of processing gas: 240, 600 or 1200 mL/min (sccm) (Here, the total flow rate of the processing gas is controlled by controlling an Ar gas flow rate in such a way that a volume flow rate ratio of O₂ gas becomes constant)

Frequency of microwave: 2.45 GHz

Power of microwave: 1100 W (power density 1.6 W/cm²)

Processing temperature: 500° C.

Processing time: 5 sec

Wafer diameter: 300 mm

As can be seen from FIG. 10, the total flow rate of the processing gas is preferably within the range of about 100 mL/min(sccm) to 500 mL/min(sccm) and more preferably within the range of about 100 mL/min(sccm) to 300 mL/min(sccm) in order to obtain a stable nitrogen dose having small variation.

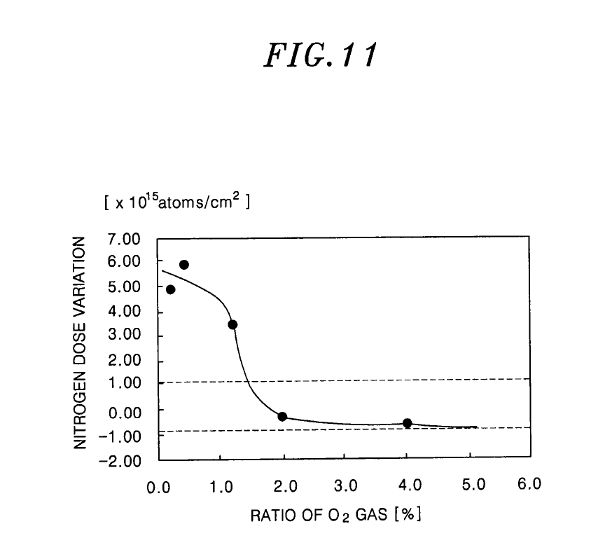

FIG. 11 shows a test result obtained by varying a volume flow rate ratio of O₂ of all the processing gases as a condition of the plasma seasoning process using a nitrogen plasma containing a trace amount of oxygen. In this test, the variation of the nitrogen dose was examined by varying the flow rate ratio of O₂ under the following plasma seasoning conditions C.

(Plasma Seasoning Condition C)

Processing pressure: 667 Pa

Ar gas flow rate: 228 mL/min(sccm)

N₂ gas flow rate: 12 mL/min(sccm)

Volume flow rate ratio of O₂ gas (O₂/total flow rate):0.20, 0.4%, 1.20, 20 or 40

Frequency of microwave: 2.45 GHz

Power of microwave: 1100 W (power density 1.6 W/cm²)

Processing temperature: 500° C.

Processing time: 5 sec

Wafer diameter: 300 mm

As can be seen from FIG. 11, the volume flow rate ratio of O₂ in all the processing gases is preferably within the range of about 1.5% to 5% and more preferably within the range of about 1.5% to 2.5% in order to obtain a stable nitrogen dose having small variation.

From the above result, it is clear that the amount of oxygen in the processing chamber 1 can be efficiently controlled by balancing a flow rate of a processing gas and a processing pressure, thereby obtaining a stable nitrogen dose having small variation. In other words, it is preferable to set the pressure in the processing chamber 1 within the range from about 532 Pa to 833 Pa and the total flow rate of the processing gas within the range from about 100 mL/min(sccm) to 500 mL/min(sccm). Further, it is preferable to set the flow rate ratio (volume ratio) of O₂ gas in all the processing gases within the range from about 1.5% to 5%.

As described above, in accordance with the present embodiment, while the first nitriding process for performing the high nitrogen-dose plasma nitriding process is shifted to the second nitriding process for performing the low nitrogen-dose plasma nitriding process, the plasma seasoning process is performed by using the nitrogen plasma containing a trace amount of oxygen under the conditions in which the pressure in the processing container (chamber) is set in a range from about 532 Pa to 833 Pa and the volume flow rate ratio of oxygen is set in a range from about 1.5% to 5%. Accordingly, the high nitrogen-dose plasma nitriding process may be quickly shifted to the low nitrogen-dose plasma nitriding process in which a stable low nitrogen dose having small variation is obtained.

Moreover, in the plasma seasoning process, the dummy wafers can be automatically moved, so that a period of time in which a user manually set the plurality of dummy wafers is unnecessary unlike the conventional case. The processing time can be reduced (improvement of throughput) since the exchange frequency of the dummy wafers is reduced. Further, the productivity is improved, and the number of steps is reduced. In addition, the production yield is improved, and the mass productivity is improved.

While the invention has been shown and described with respect to the embodiments, it will be understood by those skilled in the art that various changes and modifications may be made without departing from the scope of the invention as defined in the following claims. For example, in the above-described embodiment, the RLSA-type plasma nitriding apparatus 100 is used. However, there may be used a plasma processing apparatus of another type, e.g., a parallel plate type, an electron cyclotron resonance (ECR) plasma type, a magnetron plasma type, a surface wave plasma (SWP) type or the like.

Besides, although a wafer W having an oxide film may be used as a target object to be subjected to a plasma nitriding process in accordance with the above embodiment of the present invention, the oxide film is not limited to a SiO₂ film and may be a ferroelectric metal oxide film such as a high-k film or the like, e.g., HfO₂, Al₂O₃, ZrO₂, HfSiO₂, ZrSiO₂, ZrAlO₃, HfAlO₃, TiO₂, DyO₂, PrO₂, or a combination of at least two of them.

In the above embodiment, the plasma nitriding process using a semiconductor wafer as a target object to be processed has been described as an example. However, the plasma nitriding process may be performed on a compound semiconductor. Further, the target object may be, e.g., a substrate for a FPD (Flat Panel Display), a substrate for a solar cell, or the like.

This application claims priority to Japanese Patent Application No. 2010-81985 filed on Mar. 31, 2010, the entire contents of which are incorporated herein by reference.

What is claimed is:

1. A plasma nitriding method comprising:
carrying out a high nitrogen-dose plasma nitriding process on a target object to be processed having an oxide film by introducing a processing gas containing a nitrogen gas into a processing chamber of a plasma processing apparatus and generating a plasma containing a high nitrogen dose; and
carrying out a low nitrogen-dose plasma nitriding process on the target object by generating a plasma containing a low nitrogen dose
wherein, after the carrying out the high nitrogen-dose plasma nitriding process is completed, a plasma seasoning process is carried out in the processing chamber by generating a nitrogen plasma containing a trace amount of oxygen by introducing a rare gas, a nitrogen gas and an oxygen gas into the processing chamber and setting a pressure in the processing chamber in a range from about 532 Pa to 833 Pa and a volume flow rate ratio of the oxygen gas in all the gases in a range from about 1.5% to 5%.

2. The plasma nitriding method of claim 1, wherein a desired value of the nitrogen dose to the target object in the high nitrogen-dose plasma nitriding process equal to or greater than 10×10¹⁵ atoms/cm² and equal or to less than 50×10¹⁵ atoms/cm², and
a desired value of the nitrogen dose to the target object in the low nitrogen-does plasma nitriding process is equal to or greater than about 1×10¹⁵ atoms/cm² and less than 10×10¹⁵ atoms/cm².

3. The plasma nitriding method of claim 1, wherein the plasma is a microwave-excited plasma formed by the processing gas and a microwave introduced into the processing chamber through a planar antenna having a plurality of slots.

4. The plasma nitriding method of claim 3, wherein a power of the microwave in the plasma seasoning process ranges from about 1000 W to 1200 W.
